(19) United States
(12) Patent Application Publication
(10) Pub. No.: US 2012/0274487 A1
(43) Pub. Date: Nov. 1, 2012

(54) APPARATUS FOR ENCODING AND DECODING, DATA STORAGE APPARATUS AND METHOD FOR ENCODING AND DECODING

(75) Inventor: Yosuke Kondo, Fussa-shi (JP)

(73) Assignee: KABUSHIKI KAISHA TOSHIBA, Tokyo (JP)

(21) Appl. No.: 13/351,464

(22) Filed: Jan. 17, 2012

(30) Foreign Application Priority Data
Apr. 26, 2011 (JP) 2011-098305

(51) Int. Cl. H03M 13/00; H03M 7/00

(52) U.S. Cl. 341/94; 341/50

(57) ABSTRACT

According to one embodiment, an apparatus for encoding and decoding includes an encoder configured to generate integrated parity data for data obtained by combining first data with second data. The encoder includes a first generator, a second generator, and a third generator. The first generator generates parity data for the first data using a first check matrix with a predetermined regularity. The second generator generates parity data for the second data using a second check matrix with a regularity that is exclusive and different from the first check matrix. The third generator generates the integrated parity data by integrating the parity data generated by the first generator with the parity data generated by the second generator.

### CROSS-REFERENCE TO RELATED APPLICATIONS

This application is based upon and claims the benefit of priority from prior Japanese Patent Application No. 2011-098305, filed Apr. 26, 2011, the entire contents of which are incorporated herein by reference.

### FIELD

Embodiments described herein relate generally to an apparatus for encoding and decoding, a data storage apparatus, and a method for encoding and decoding.

### BACKGROUND

In general, data storage apparatuses and communication apparatuses include an error correction function incorporated therein to detect and correct errors in data. An example of a typical well-known method for implementing the error correction function is a method for encoding and decoding using Hamming codes.

The method for encoding and decoding comprises, for example, an encoding operation of generating parity data for user data (information bit sequence) stored in a data storage apparatus and a decoding operation of detecting errors in the user data using the parity data.

An apparatus for encoding and decoding adopting the method for encoding and decoding can detect and correct errors occurring in the user data stored in the data storage apparatus. In this connection, the data storage apparatus handles, as data stored in a storage medium, not only the user data, which serves as main data, but also related data (hereinafter referred to as extra data) other than the user data, for example, address data and various management data.

The extra data is desirably subjected to an error detection and correction process by the apparatus for encoding and decoding. However, if the extra data is encoded and decoded independently of the user data, the apparatus for encoding and decoding is likely to have reduced processing efficiency and a complicated configuration.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is a block diagram illustrating a configuration of an apparatus for encoding and decoding according to an embodiment;

FIG. 2 is a block diagram showing a main part of a disk drive according to the embodiment;

FIG. 3 is a block diagram showing a main part of an SSD according to the embodiment;

FIG. 4 is a diagram illustrating a configuration of a check matrix according to the embodiment;

FIG. 5 is a block diagram illustrating a configuration of a logic module according to the embodiment;

FIG. 6 is a flowchart illustrating an operation of an encoder according to the embodiment; and

FIG. 7 is a flowchart illustrating an operation of a decoder according to the embodiment.

### DETAILED DESCRIPTION

Various embodiments will be described hereinafter with reference to the accompanying drawings.

In general, according to one embodiment, an apparatus for encoding and decoding includes an encoder configured to generate integrated parity data for data obtained by combining first data with second data. The encoder includes a first generator, a second generator, and a third generator. The first generator generates parity data for the first data using a first check matrix with a predetermined regularity. The second generator generates parity data for the second data using a second check matrix with a regularity that is exclusive and different from the first check matrix. The third generator generates the integrated parity data by integrating the parity data generated by the first generator with the parity data generated by the second generator.

[Configuration of the Apparatus for Encoding and Decoding]

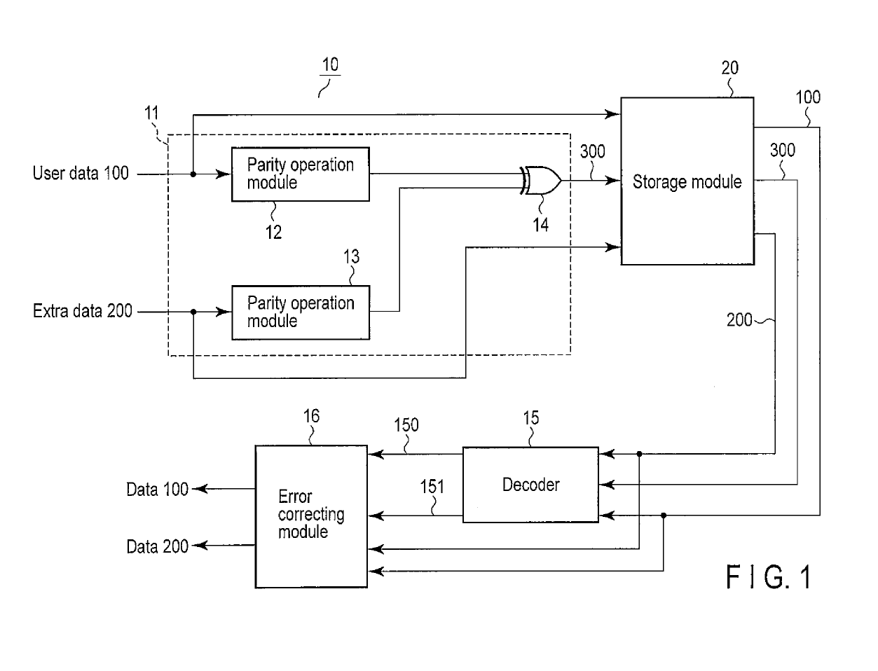

FIG. 1 is a block diagram illustrating a configuration of an apparatus for encoding and decoding according to an embodiment.

As shown in FIG. 1, an apparatus for encoding and decoding 10 comprises an encoder 11, a decoder 15, and an error correction module 16. The apparatus for encoding and decoding is formed of, for example, an integrated circuit on one chip. In the present embodiment, as described below, the apparatus for encoding and decoding 10 is applied to a data storage apparatus such as a hard disk drive or solid-state drive (SSD).

The encoder 11 receives user data 100 and extra data 200 as input data and carries out an encoding process based on a Hamming encoding method. The encoder 11 comprises a parity operation module for user data (first parity operation module) 12, a parity operation module for extra data (second parity operation module) 13, and an exclusive-OR (XOR) gate 14.

An encoding process carried out by the encoder 11 will be described below with reference to a flowchart in FIG. 6.

The encoder 11 receives the user data 100 and the extra data 200 as input data (block 600). Here, the user data 100 is main data transferred from, for example, a host system, and saved to a storage medium in a storage module 20. The extra data 200 is additional data associated with the user data 100, for example, logical block address (LBA) data and management data on the system of the data storage apparatus.

The first parity operation module 12 uses a predetermined generator matrix to generate parity data for the user data 100 (block 601). The second parity operation module 13 uses a generator matrix different from that of the first parity operation module 12, to generate parity data for the extra data 200 (block 602).

The XOR gate 14 performs an exclusive-OR operation using, as an input, the parity data output by the first and second parity operation modules 12 and 13. The XOR gate 14 thus calculates integrated parity data 300 (block 603). That is, the integrated parity data 300 is parity data for data obtained by combining the user data 100 with the extra data 200.

The storage module 20 is a main element of the data storage apparatus. The storage module 20 stores the user data 100, the extra data 200, and the integrated parity data 300 (block 604). In this case, in the storage module 20, the user data 100 is stored in a user area of the storage medium. The extra data 200 is stored in a system area of the storage medium. Furthermore, the integrated parity data 300 is stored in the user area together with the user data 100.

The decoder 15 receives the user data 100, the extra data 200, and the integrated parity data 300 from the storage module 20. The decoder 15 uses a predetermined check matrix corresponding to the generator matrix or a transposed matrix for the check matrix to carry out an error detecting process.

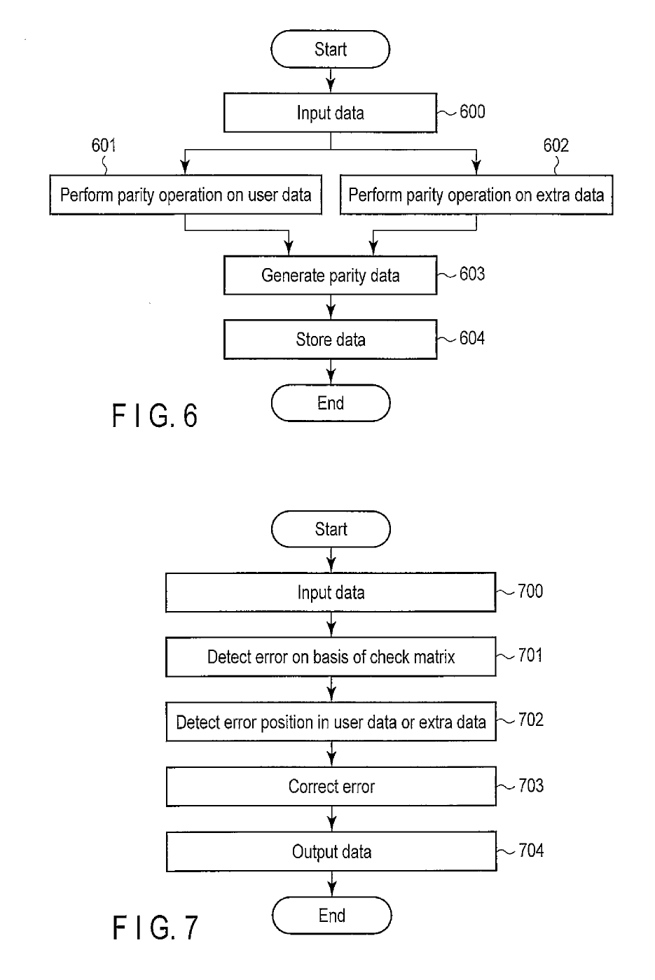

A decoding process and an error correction process carried out by the decoder 15 will be described with reference to a flowchart in FIG. 7.

The decoder 15 receives the user data 100, the extra data 200, and the integrated parity data 300 from the storage module 20 (block 700). The decoder 15 uses the integrated parity data 300 to determine whether or not the user data 100 and the extra data 200 are erroneous on the basis of a check matrix 400 described below. The decoder 15 thus achieves error detection (block 701). Depending on the error determination, the decoder 15 outputs a flag 151 indicating that an error has been detected.

Moreover, the decoder 15 performs a syndrome operation. On the basis of the syndrome operation, the decoder 15 generates a syndrome 150 indicative an error position (error address) in each of the user data 100 and the extra data 200 (block 702).

In accordance with the flag 151 from the decoder 15, the error correction module 16 corrects the error present in the user data 100 and extra data 200 on the basis of the syndrome from the decoder 15, and then outputs the corrected data (blocks 703 and 704).

In the present embodiment, the generator matrix, the corresponding check matrix, and the transposed matrix for the check matrix are hereinafter each referred to as the check matrix for convenience.

Moreover, the apparatus for encoding and decoding 10 may carry out a process of delivering the extra data 200 using the same data bus as that used for the user data 100. In this case, the user data 100 and the extra data 200 need to be distinguished from each other by utilizing a signal indicative of the extra data 200 or an internal counter. Furthermore, if the extra data is transmitted on a data bus different from that used for the user data 100, the first and second parity operation modules 12 and 13 can operate in parallel. Additionally, if the extra data 200 is established before all of the user data 100 is delivered, a parity operation on the extra data 200 can be completed during a parity operation on the user data 100. Thus, the parity data for the extra data 200 can be output when the parity operation on the user data is completed. This eliminates the need for a parity operation cycle for the extra data 200.

(Configuration of the Data Storage Apparatus)

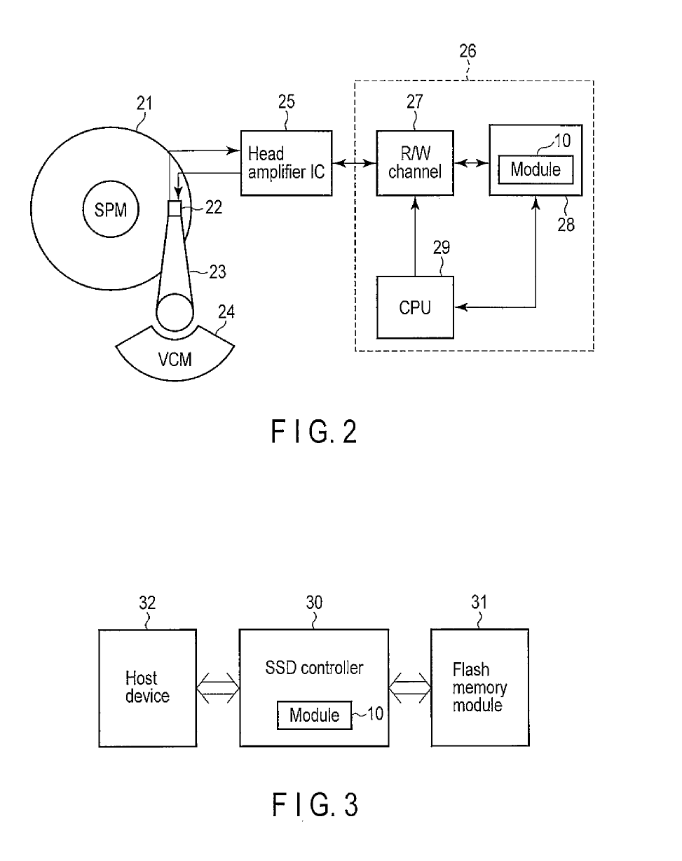

FIG. 2 and FIG. 3 are diagrams illustrating specific examples of a storage apparatus to which the apparatus for encoding and decoding 10 according to the present embodiment is applied and which includes the storage module 20.

FIG. 2 is a block diagram showing a main part of a hard disk drive (HDD) serving as the data storage apparatus. FIG. 3 is a block diagram showing a main part of a solid-state drive (SSD) serving as the data storage apparatus.

As shown in FIG. 2, an HDD generally comprises a head-disk assembly (HDA), a head amplifier integrated circuit (IC) 25, and a circuit board 26. The HDA comprises a disk 21 serving as a storage medium, an arm 23 with a head 22 mounted thereon, and a voice coil motor (VCM) 24.

The disk 21 is rotated by a spindle motor (SPM). The arm 23 and VCM 24 form an actuator. The actuator is driven by the VCM 24 to controllably move the head 22 mounted on the arm 23 to a specified position over the disk 21. The head 22 comprises a read head element and a write head element. The read head element reads data recorded on the disk 21. The write head element writes data onto the disk 21.

The head amplifier IC 25 comprises a read amplifier and a write driver. The read amplifier amplifies a read signal read by the read head element. The read amplifier then transmits the amplified read signal to a read/write (R/W) channel 27. In contrast, the write driver transmits a write current corresponding to write data output by the R/W channel 27, to the write head element.

The circuit board 26 includes the R/W channel 27, a disk controller 28, and a microprocessor (CPU) 29. The R/W channel 27 includes a read channel configured to carry out signal processing on read data and a write channel configured to carry out signal processing on write data. The CPU 29 is a main controller for the drive, and performs servo control for positioning the head 22 and data read/write control.

The disk controller 28 performs interface control for controlling data transfer between the host system and the R/W channel 27. The disk controller 28 includes a module corresponding to the apparatus for encoding and decoding 10. The storage module 20 shown in FIG. 1 includes, as a storage medium, a buffer memory formed of DRAM, in addition to the disk 21.

As shown in FIG. 3, an SSD generally comprises an SSD controller 30 and a flash memory module 31. The SSD controller 30 controls data transfer to and from a host device (interface controller) 32 included in the host system. The SSD controller 30 further performs data read/write control on the flash memory module 31. The storage module 20 shown in FIG. 1 also includes, as a storage medium, a buffer memory formed of DRAM, in addition to the flash memory module 31.

[Process for Encoding and Decoding]

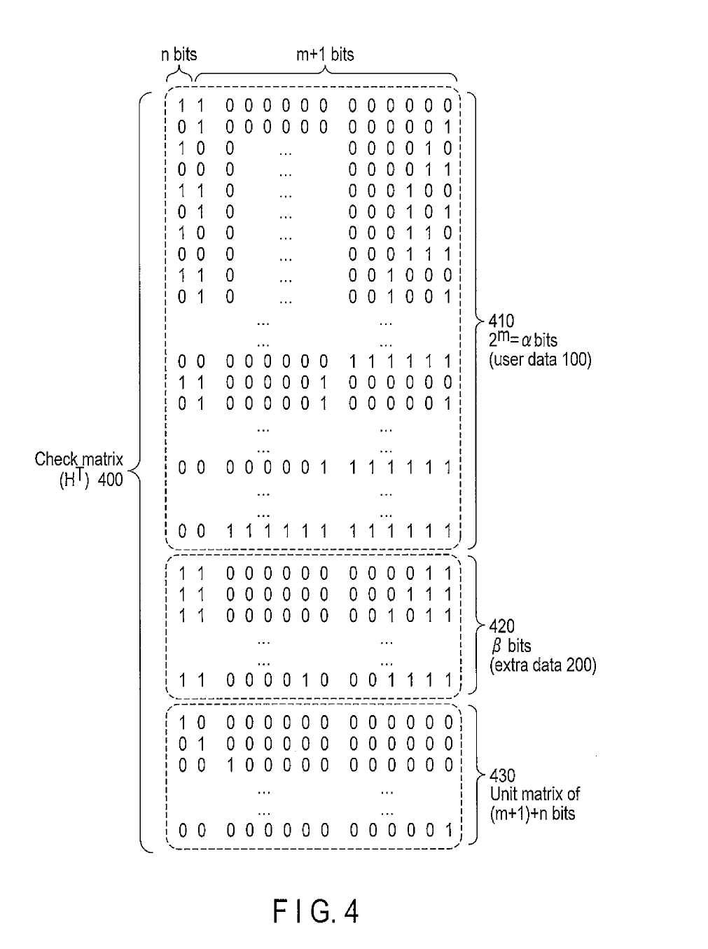

A process for encoding and decoding according to the present embodiment will be specifically described below with reference to FIG. 4 to FIG. 7.

FIG. 4 is a diagram showing a specific example of configuration of a check matrix (transposed matrix HT) 400 used for the process for encoding and decoding carried out by the apparatus for encoding and decoding 10.

As shown in FIG. 4, the check matrix 400 according to the present embodiment comprises a check matrix (check matrix A) 410 corresponding to the user data 100, a check matrix (check matrix B) 420 corresponding to the extra data, and a unit matrix ((m+1)+n bits) of systematic codes 430. Each of the check matrices 410, 420, and 430 includes row components that are all exclusive and is formed as a check matrix of Hamming codes that enable 1-bit corrections.

In the check matrix (A) 410, given that parity data generated by the first parity operation module 12 contains p bits, first, m rightmost columns in the matrix are used to arrange of α=2^{m} (2^{m}=α bits) combinations of bits in ascending or descending order. Then, combinations of the bits from the m+1th column to the p^{th} column from the right end of the matrix are set such that the number of is in the row is at least two. This leads to formation of the check matrix (A) 410 for the user data 100 of α bits (=2^{m}).

In contrast, unlike in the case of the rule for (the regularity of) the check matrix (A) 410, a check matrix (B) 420 has an exclusive configuration and is configured to be able to detect the position of an error (1-bit error) in the extra data 200. That is, the check matrix (B) 420 corresponds to the extra data 200 formed of β bits unlike the user data 100 formed of α bits. In the check matrix (B) 420, β combinations of bits are arranged at any positions in the matrix in ascending or descending order. At the remaining positions, combinations of bits are arranged so as to avoid overlapping the rows set in the check matrix (A) 410.

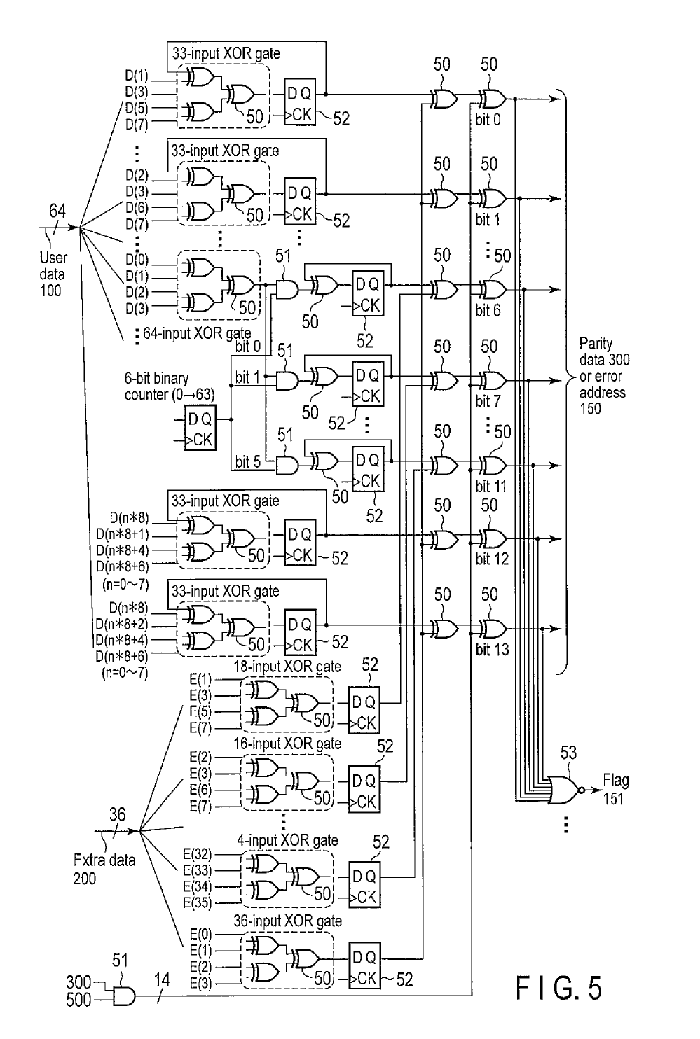

FIG. 5 is a block diagram showing a configuration of a logic module for specifically implementing the apparatus for encoding and decoding 10 configured to carry out a process for Hamming encoding and decoding using the check matrix 400 shown in FIG. 4.

As shown in FIG. 5, the logic module comprises exclusive-OR (XOR) gates 50, AND gates 51, flip-flops 52, and NOR gates 53.

The AND gate 51 forms a logic that allows an encoding process and a decoding process to be switched. That is, the AND gate 51 receives the integrated parity data 300 at one input thereof and a signal 500 at the other input; the signal 500 specifies one of encoding and decoding. The logic module receives, as input data, for example, the user data 100 of 64 bits and the extra data 200 of 36 bits per clock.

In the encoding process, the AND gate 51 receives the signal 500 (0) specifying encoding, at the other input thereof. In the encoding process, the configuration of an input-side circuit with a plurality of 33-input XOR gates and 64-input XOR gates corresponds to a parity operation on the 64-bit user data 100 and the check matrix (A) 410. Furthermore, the configuration of an input-side circuit with a plurality of 18-input XOR gates, 10-input XOR gates, 4-input XOR gates, and 36-input XOR gates corresponds to a parity operation on the 36-bit extra data 200 and the check matrix (B) 420. The encoding process generates, for example, 14-bit integrated parity data 300.

In contrast, in the decoding process, the AND gate 51 receives the integrated parity data 300 at one input thereof and the signal 500 (1) specifying decoding, at the other end thereof. The decoding process allows the above-described decoder 15 to carry out a syndrome operation to generate an error address (that is, a syndrome) 150 indicative of an error position in each of the user data 100 and the extra data 200. Furthermore, the NOR gate 53 outputs a flag 151 indicating that an error has been detected.

Then, as shown in FIG. 4, in the check matrix (A) 410 included in the check matrix 400 according to the present embodiment and corresponding to the user data 100, the 1^{st} to 12^{th} bits from the right end of the matrix are used to arrange 2^{m} (2^{m}=α bits) combinations of bits in ascending or descending order. Furthermore, the 1st and 2nd bits from the left end of the matrix are arranged in conjunction with the 1st and 2nd bits from the right end of the matrix so that these 4 bits include two 1s.

In contrast, in the check matrix (B) 420 corresponding to the extra data 200, the 3rd to 12th bits from the right end of the matrix are used to arrange 36 combinations of bits in ascending or descending order. Furthermore, the combination of the 1st and 2nd bits from the left end of the matrix and the 1st and 2nd bits from the right end of the matrix is arranged so that these 4 bits include four 1s, thus forming the pattern 1111.

In short, 4 bits in the check matrix (A) 410 corresponding to the user data 100 has a combination (bit pattern) different from that of four bits at the same position in the check matrix (B) 420 corresponding to the extra data 200. Thus, the combination of the 4 bits in the check matrix (B) may be 1110, including three 1s, instead of the pattern 1111.

As described above, in the decoding process, the combination pattern of 4 bits is distinctly different between the check matrix used for the user data 100 and the check matrix used for the extra data 200. Thus, if a syndrome operation results in a 1-bit error in one of the user data 100 and the extra data 200, which of the data is erroneous can be determined from the combination pattern of the 4 bits.

Moreover, the syndrome 150 calculated by the decoder 15 is directly indicative of the error position. Thus, regardless of which of the user data 100 and the extra data 200 is erroneous, no operation needs to be performed in order to calculate the error position (error address) from the syndrome 150. For example, if the extra data 200 is formed of 36 bits and a 1-bit error occurs in the extra data, the error address [7:2] is directly indicative of the error position in the extra data.

As described above, the apparatus for encoding and decoding according to the present embodiment can almost simultaneously carry out the process for encoding and decoding on both the user data 100 and the extra data (related data) 200, which are handled by the data storage apparatus. Specifically, in the encoding process, integrated parity data can be generated which corresponds to data obtained by integrating the user data 100 with the extra data 200. Furthermore, in the decoding process, the integrated data can be decoded to allow an error in each of the user data 100 and the extra data 200 to be detected and corrected.

Thus, the process for Hamming encoding and decoding can be carried out on the integrated data at high speed so as to enable 1-bit corrections. Furthermore, the small-scale, simple logic module can be used to implement the parity operation configuration corresponding to each of the user data 100 and the extra data 200. Hence, in particular, the apparatus for encoding and decoding enabling 1-bit corrections can be incorporated into a data storage apparatus such as an HDD or SSD to not only protect the user data but also simultaneously protect the extra data, related to the user data.

In the above description, the apparatus for encoding and decoding according to the present embodiment is applied to the data storage apparatus. However, the present embodiment is not limited to this configuration. The apparatus for encoding and decoding according to the embodiment is applicable to a communication apparatus such as a wireless communication apparatus.

The various modules of the embodiments described herein can be implemented as software applications, hardware and/or software modules, or components on one or more computers, such as servers. While the various modules are illustrated separately, they may share some or all of the same underlying logic or code. While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An apparatus for encoding and decoding, comprising:
an encoder configured to generate integrated parity data for data obtained by combining first data with second data, wherein the encoder comprises:
a first generator configured to generate a first parity data for the first data using a first check matrix with a first regularity;
a second generator configured to generate a second parity data for the second data using a second check matrix with a second regularity that is exclusive and different from the first check matrix; and
a third generator configured to generate the integrated parity data by integrating the first parity data with the second parity data.

2. The apparatus of claim 1, further comprising:
a decoder configured to detect an error in each of the first and second data using the integrated parity data,
wherein the decoder is configured to detect a first error in the first data on the basis of the first check matrix and to detect a second error in the second data on the basis of the second check matrix.

3. The apparatus of claim 1, wherein the third generator comprises a logic module configured to receive, as an input, each of the first and second parity data and to perform an exclusive-OR operation to calculate the integrated parity data.

4. A data storage apparatus comprising:
an apparatus for encoding and decoding comprising an encoder configured to generate integrated parity data for data obtained by combining first data with second data, wherein the encoder comprises,
a first generator configured to generate a first parity data for the first data using a first check matrix with a first regularity,
a second generator configured to generate a second parity data for the second data using a second check matrix with a second regularity that is exclusive and different from the first check matrix, and
a third generator configured to generate the integrated parity data by integrating the first parity data with the second parity data;
a storage device configured to store user data that is the first data, extra data that is the second data, and the integrated parity data; and
an interface configured to output the user data or the extra data read from the storage device, to an external device.

5. The data storage apparatus of claim 4, further comprising:
a decoder configured to detect a first and second error in the first and second data respectively using the integrated parity data, wherein the decoder is configured to detect the first error in the first data on the basis of the first check matrix and to detect the second error in the second data on the basis of the second check matrix, and
an error correction module configured to correct the first and second error detected by the decoder,
wherein the decoder is configured to detect an error in each of the user data and the extra data read from the storage device.

6. The data storage apparatus of claim 4, further comprising:
a controller configured to store the user data with the integrated parity data added thereto, in the storage device and to store the extra data in a storage area of the storage device which is managed differently from a storage area in which the user data is stored.

7. A method for encoding and decoding, the method comprising:
generating a first parity data for first data using a first check matrix with a first regularity;
generating a second parity data for second data using a second check matrix with a second regularity that is exclusive and different from the first check matrix; and
generating integrated parity data by integrating the first parity data with the second parity data.

8. The method of claim 7, further comprising:
detecting a first and second error in the first and second data respectively using the integrated parity data,
wherein the detection of the first and second error comprises detecting a first error in the first data on the basis of the first check matrix, and
detecting a second error in the second data on the basis of the second check matrix.

9. The method of claim 7, wherein the generation of the integrated parity data is configured to receive, as an input, each of the first and second parity data and to perform an exclusive-OR operation to calculate the integrated parity data.

10. The method of claim 7, further comprising:
storing user data that is the first data, extra data that is the second data, and the integrated parity data, in a storage device of a data storage apparatus.

11. The method of claim 10, further comprising:
detecting an error in each of the user data and the extra data using the integrated parity data read from the storage device,
wherein the detection of the error comprises detecting an error in the user data on the basis of the first check matrix, and
detecting an error in the extra data on the basis of the second check matrix.
